(19) United States
(12) Patent Application Publication
(10) Pub. No.: US 2016/0355648 A1
(43) Pub. Date: Dec. 8, 2016

(54) RESIN FILM

(71) Applicant: C.I. KASEI COMPANY, LIMITED, Tokyo (JP)

(72) Inventor: Hitoshi SUGIYAMA, Kusatsu-shi (JP)

(21) Appl. No.: 15/111,451

(22) PCT Filed: Feb. 2, 2015
(86) PCT No.: PCT/JP2015/052847

§ 371 Date: Jul. 13, 2016

(30) Foreign Application Priority Data
Feb. 19, 2014 (JP) 2014-029642

(51) Int. Cl. C08J 5/18; B32B 17/06; H01L 31/048; C08K 5/07; C08K 5/5435

(52) U.S. Cl. CPC C08J 5/18; C08K 5/07; C08K 5/5435; H01L 31/0481; B32B 17/064; C08J 2323/08; B32B 2457/00

(57) ABSTRACT

A resin film including a copolymer having a constituent unit derived from ethylene, a constituent unit derived from a (meth)acrylic acid ester and a constituent unit derived from a monomer having a glycidyl group; a benzophenone-based ultraviolet absorber; and a silane coupling agent having an epoxy group.

### TECHNICAL FIELD

The present invention relates to a resin film. Priority is claimed on Japanese Patent Application No. 2014-029642, filed Feb. 19, 2014, the content of which is incorporated herein by reference.

### BACKGROUND ART

Resin films have been widely used as an interlayer in laminated glass used for automobiles, railway vehicles, aircrafts, ships, buildings or the like, and as a sealing material used in solar cell modules, and the like.

More specifically, in the laminated glass, the resin film is used as an interlayer in a laminated constitution of glass plate/interlayer/glass plate, glass plate/interlayer/polyethylene terephthalate film (hereinafter, referred to as a PET film)/interlayer/glass plate or the like. In the solar cell module, the resin film is used as a sealing material which forms a sealing material layer in a laminated constitution of glass plate/sealing material layer having cells encapsulated therein/backsheet, and so on.

Generally, a silane coupling agent is mixed with a resin film used in an, interlayer of laminated glass, a sealing material for a solar cell module or the like to increase adhesion to the glass plate. Further, an ultraviolet absorber is mixed with the aforementioned resin film for the purpose of, for example, suppression of the degradation of a resin due to ultraviolet rays by shielding it from ultraviolet rays.

As an interlayer of laminated glass, for example, an interlayer (Patent Document 1) which includes a copolymer having a constituent unit derived from ethylene, a constituent unit derived from (meth)acrylate acid ester, and a constituent unit derived from a monomer containing a glycidyl group, a silane coupling agent containing an amino group, and an ultraviolet absorber has been proposed.

As a sealing material for a solar cell module, for example, a sealing material for a solar cell module (Patent Document 2) including an ethylene-vinyl acetate copolymer, a crosslinking agent, 2-hydroxy-4-n-octoxybenzophenone which is an ultraviolet absorber, and a silane coupling agent has been suggested.

### DOCUMENT OF RELATED ART

### Patent Document

### [Patent Document 1]

PCT International Publication No. WO2010/090212

### [Patent Document 2]

Japanese Unexamined Patent Application, First Publication No. 2011-238862

### SUMMARY OF INVENTION

### Technical Problem

However, the interlayer of Patent Document 1 has difficulty in achieving excellent transparency.

Moreover, as a result of the study of the present inventors, it was confirmed that when a benzophenone-based ultraviolet absorber was used in the interlayer of Patent Document 1, quality of the interlayer was degraded because the interlayer yellowed in an early stage of manufacturing. Furthermore, it was also confirmed that quality of a sealing material may be degraded due to yellowing in the case of the sealing material for a solar cell module of Patent Document 2.

An objective of the present invention is to provide a resin film which is usable as a laminated glass interlayer or a sealing material for a solar cell module or the like, has excellent adhesion to a glass plate and excellent ultraviolet ray shielding properties, and does not yellow in an early stage of manufacturing as well as being capable of limiting yellowing.

### Solution to Problem

In order to achieve the aforementioned objects, the present invention employs the following constitutions.

[1] A resin film, including: (A) a copolymer having a constituent unit derived from ethylene, a constituent unit derived from a (meth)acrylic acid ester and a constituent unit derived from a monomer having a glycidyl group; (B) a benzophenone-based ultraviolet absorber; and (C) a silane coupling agent having an epoxy group.

[2] The resin film according to the above-described [1], which is a laminated glass interlayer

[3] The resin film according to the above-described [1], which is a sealing material for a solar cell module.

### ADVANTAGEOUS EFFECTS OF INVENTION

The resin film, according to the present invention is a resin film which is usable as a laminated glass interlayer or a sealing material for a solar cell module or the like, has excellent adhesion to a glass plate and excellent ultraviolet ray shielding properties, and does not yellow in an early stage of manufacturing as well as being capable of limiting yellowing.

### DESCRIPTION OF EMBODIMENTS

### <Resin Film>

A resin film according to the present invention may include a copolymer (A), a benzophenone-based ultraviolet absorber (B) (hereinafter, simply referred to as an ultraviolet absorber (B)); and a silane coupling agent having an epoxy group (C) (hereinafter, simply referred to as a silane coupling agent (C)). Further, the resin film according to the present invention may include a polymer (D) and an additive (E) other than the copolymer (A), as necessary.

### [Copolymer (A)]

The copolymer (A) is a copolymer having a constituent unit derived from ethylene (hereinafter, referred to as a constituent unit (α1)), a constituent unit derived from a (meth)acrylic acid ester (hereinafter, referred to as a constituent unit (α2)), and a constituent unit derived from a monomer having a glycidyl group (hereinafter, referred to as a constituent unit (α3)). The resin film according to the present invention may be a resin, film with excellent adhesion to a PET film or a glass plate and excellent transparency by containing the copolymer (A).

As the (meth)acrylic acid ester, a compound represented by the following Structural Formula 1 (hereinafter, referred to as a compound (1)) is preferable in terms of improvement in adhesion to a PET film or glass plate and transparency.

CH₂═CR¹—CO—O—R² (1)

(where R¹ is a hydrogen atom or a methyl group, and R² is an alkyl group having 1 to 5 carbon atoms)

R² of the compound (1) may be in the form of a straight chain or a branched chain.

R² is preferably an alkyl group having 1 to 3 carbon atoms, more preferably, a methyl group or ethyl group, and still more preferably, a methyl group in terms of improvement of adhesion to a PET film or a glass plate.

The constituent unit (α2) included in the copolymer (A) may be one type or two or more types.

As the monomer, having a glycidyl group, a compound represented by the following Structural Formula 2 (hereinafter, referred to as a compound (2)) is preferable in terms of improvement of adhesion to a PET film or a glass plate and transparency

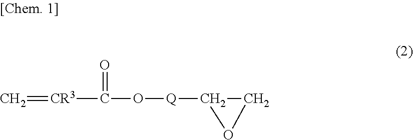

(where R³ is a hydrogen atom or a methyl group, and Q is an alkylene group having 1 to 5 carbon atoms)

Q of the compound (2) may be in the form of a straight chain or a branched chain.

Q is preferably an alkylene group having 1 to 3 carbon atoms, more preferably, a methylene group or an ethylene group, and still more preferably a methylene group in terms of improvement of adhesion to a PET film or a glass plate.

The constituent unit (α3) included in the copolymer (A) may be one type, or two or more types.

### (Ratio of Each Constituent Unit)

The ratio of the constituent (α1) with respect to all the constituent units forming the copolymer (A) is preferably in the range of 50 to 85 mass %, more preferably, 60 to 78 mass %, and still more preferably 65 to 75 mass %. When the ratio of the aforementioned constituent unit (α1) is equal to or higher than the lower limit value, blocking of resin films to each other may be easily controlled during storage. When the ratio of the aforementioned constituent unit (α1) is equal to or lower than the upper limit value, a resin film having excellent transparency may be easily obtained.

The ratio of the constituent (α2) with respect to all the constituent units forming the copolymer (A) is preferably in the range of 10 to 48 mass %, more preferably, 15 to 38 mass %, and still more preferably, 23 to 28 mass %. When the ratio of the aforementioned constituent unit (α2) is equal to or higher than the lower limit value, the thermal processability is excellent. When the ratio of the aforementioned constituent unit (α2) is equal to or lower than the upper limit value, blocking may be easily controlled.

The ratio of the constituent (α3) with respect to all the constituent units forming the copolymer (A) is preferably in the range of 1 to 20 mass %, more preferably, 2 to 15 mass %, and still more preferably, 5 to 10 mass %. When the ratio of the aforementioned constituent unit (α3) is equal to or higher than the lower limit value, adhesion to a PET film or a glass plate is excellent. When the ratio of the aforementioned constituent unit (α3) is equal to or lower than the upper limit value, the transparency is excellent.

The ratio of each constituent unit of the copolymer (A) may be measured using a method in accordance with ISO 8985. An example of a measuring device includes Fourier Transform Infrared Spectrometer (FT-IR). The copolymer (A) may be one type, or two or more types.

The amount of the copolymer (A) in the resin film (100 mass %) according to the present invention is preferably in the range of 60 to 99.8 mass %, more preferably, 70 to 99 mass %, and still more preferably, 95 to 98 mass %. When the amount of the aforementioned copolymer (A) is equal to or higher than the lower limit value, a resin film which is excellent in adhesion to a PET film or a glass plate and transparency may be easily obtained. When the amount of the aforementioned copolymer (A) is equal to or lower than the upper limit value, excellent weather resistance, may be easily obtained.

### [Ultraviolet Absorber (B)]

An ultraviolet absorber (B) is a benzophenone-based ultraviolet absorber.

Examples of the ultraviolet absorber (B) include 2-hydroxy -4-n-octoxybenzophenone, 2-hydroxy-4-methoxy-benzophenone, 2,4-dihydroxybenzophenone 2,2′-dihydroxy-4,4′-dimethoxy benzophenone, 2,2′,4,4′-tetrahydroxybenzophenone, 2,2′-dihydroxy-4-methoxybenzophenone, etc. Among them, those having a hydroxyl group on each aromatic ring is preferable, and 2,2′-dihydroxy-4,4′-dimethoxy benzophenone is more preferable in terms of easily obtaining a resin film which has ultraviolet absorbing performance with the wavelength of around 400 nm and shields ultraviolet rays in a wide wavelength range.

The ultraviolet absorber (B) may be one type, or two or more types.

The amount of the ultraviolet absorber (B) in the resin film (100 mass %) according to the present invention is preferably in the range of 0.1 to 1.0 mass %, more preferably, 0.2 to 0.8 mass %, and still more preferably, 0.3 to 0.5 mass %. When the amount of the aforementioned ultraviolet absorber (B) is equal to or higher than the lower limit value, a resin film which is excellent in ultraviolet ray shielding properties may be easily obtained. When the amount of the aforementioned ultraviolet absorber (B) is equal to or lower than the upper limit value, the initial coloring property thereof may be suppressed.

### [Silane Coupling Agent (C)]

A silane coupling agent (C) is a silane coupling agent (C) having an epoxy group. The resin film according to the present invention may be a resin film which is excellent in adhesion to a glass plate by containing the silane coupling agent (C). Moreover, the adhesion to a glass plate and ultraviolet ray shielding properties of the resin, may be improved, yellowing in an early stage of manufacturing may be limited, and yellowing may also be limited by a combination of the ultraviolet absorber (B) and the silane coupling agent (C).

Examples of the silane coupling agent (C) include 3-glycidyloxypropyltrimethoxysilane, 3-glycidyloxypropyltriethoxysilane, 3-glycidoxypropylmethyldiethoxysilane, etc. Among them, 3-glycidyloxypropyltrimethoxysilane is preferable in terms of adhesion during low temperature processing.

The silane coupling agent (C) may be one type or two or more types.

The amount of the silane coupling agent (C) in the resin film (100 mass %) according to the present invention is preferably in the range of 0.01 to 2.0 mass %, more preferably, 0.05 to 1.0mass %, and still more preferably 0.1 to 0.3 mass %. When the amount of the aforementioned silane coupling agent (C) is equal to or higher than the lower limit value, a resin film having excellent adhesion to a glass plate may be easily obtained. When the amount of the aforementioned silane coupling agent (C) is equal to or lower than the upper limit value, the occurrence of degradation in transparency becomes difficult.

### [Polymer (D)]

The resin film according to the present invention may include a polymer (D) other than the copolymer (A).

Examples of the polymer (D) include an ethylene-vinyl, acetate copolymer (hereinafter, referred to as EVA), an ethylene-vinyl acetate-glycidyl (meth)acrylate copolymer, an ethylene-glycidyl (meth)acrylate copolymer, a polyvinyl acetal resin, a vinyl chloride resin, an acid-modified polyolefin, polyethylene, and so on.

The acid-modified polyolefin is a polyolefin modified with an acid. Examples of the acid modifying the polyolefin include maleic acid, fumaric acid, chloro-maleic acid, himic acid, citraconic acid, itaconic acid, and so on.

EVA is preferable as the polymer (D) from the viewpoint of cost.

The ratio of a constituent unit derived from vinyl acetate in EVA is preferably 20 to 40 mass %, and more preferably, 25 to 33 mass % with respect to all the constituent units forming the copolymer (A). When the ratio of the aforementioned constituent unit derived from vinyl acetate is equal to or higher than the lower limit value, a resin film with high transparency may be easily obtained. When the ratio of the aforementioned constituent unit derived from vinyl acetate is equal to or lower than the upper limit value, the occurrence of blocking becomes difficult.

The polymer (D) may be one type or two or more types.

When the resin film according to the present invention includes the polymer (D), the amount of the polymer (D) in the resin film (100 mass %) according to the present invention is preferably in the range of 5 to 50 mass %, more preferably, 10 to 40 mass %, and still more preferably, 15 to 30 mass %. When the amount of the aforementioned polymer (D) is equal to or higher than the lower limit value, it is possible to keep costs low. When the amount of the aforementioned polymer (D) is equal to or lower than the upper limit value, a resin which is excellent in adhesion to a PET film or a glass plate, and transparency may be easily obtained.

When the resin film according to the present, invention includes the polymer (D), the ratio of the copolymer (A) with respect to a total mass (100 mass %) of the copolymer (A) and the polymer (D) is preferably in the range of 5 to 50 mass %, more preferably, 10 to 40 mass %, and still more preferably, 15 to 30 mass %. When the ratio of the aforementioned copolymer (A) is equal to or higher than the lower limit value, a resin which is excellent in adhesion to a PET film or a glass plate and transparency may be easily obtained. When the ratio of the aforementioned copolymer (A) is equal to or lower than the upper limit value, it is possible to keep costs low.

### [Additive (E)]

The resin film according to the present invention, if necessary, may include an additive (E).

Examples of the additive (E) include an ultraviolet absorber other than the ultraviolet absorber (B), a crosslinking agent, a crosslinking aid, a sunscreen, a colorant (a pigment, a dye, etc.), an antioxidant, a plasticizer, a light stabilizer, a flame retardant, an antistatic agent, a moisture resistant agent, a heat reflecting agent, a heat absorber, and so on.

Examples of the ultraviolet absorber other than the ultraviolet absorber (B) include a benzotriazole ultraviolet absorber, a salicylate ester-based ultraviolet absorber, and so on.

The additive (E) may be one type or two or more types.

When the resin film according to the present invention include the additive (E), The amount of the additive (E) in the resin, film (100 mass %) according to the present invention is preferably in the range of 0.1 to 10 mass %, more preferably, 0.2 to 5 mass %, and still more preferably, 03 to 2.0 mass %.

The thickness of the resin, film according to the present invention is preferably in the range of 0.1 to 3.0 mm, and more preferably, 0.4 to 1.0 mm. When the thickness of the resin film is equal to or higher than the upper limit value, the resin film exhibits excellent ultraviolet ray shielding properties. When the thickness of the resin film is equal to or lower than the upper limit value, the resin film is excellent in workability during processing.

### [Preparation Method]

There is no particular limitation on the preparation method of the resin film according to the present invention, and examples thereof include a method of kneading the copolymer (A), the ultraviolet absorber (B) and the silane coupling agent (C), and the polymer (D) and the additive (E) used when necessary, to obtain a resin composition, and then forming the aforementioned resin composition into a sheet, and so on.

The kneading method includes, for example, methods using an extruder, a plastograph, a kneader, a Banbury mixer, a calender roll, and so on. The method of forming a sheet includes, for example, an extrusion molding method using a T-die, a press molding method, and so on, Further, in the case of a resin composition solution, a sheet may be formed by applying the resin composition onto a release sheet, and drying the resin composition.

### [Use]

There is no particular limitation on a use of the resin film according to the present, invention, but a use as a laminated glass interlayer or a sealing material for a solar cell module is preferred.

As for laminated glass in which the resin film according to the present invention is used as a laminated glass interlayer, a known constitution may be employed except for using the resin film according to the present invention. Examples thereof include laminated glass which has a laminated constitution of glass plate/first interlayer/PET film/second interlayer/glass plate and includes the resin film according to the present invention used in either or both of the aforementioned first interlayer and the aforementioned second interlayer. In this case, it is preferable to use the resin film according to the present invention in both of the first interlayer and the second interlayer. In addition, laminated glass may have a laminated constitution of glass plate/interlayer/glass plate and include the resin film according to the present invention used in the aforementioned interlayer.

As for the solar cell module in which the resin film according to the present invention is used as a sealing material for a solar cell module, a known constitution may be employed except for using the resin film according to the present invention. Examples thereof include a solar cell module which has a laminated constitution of glass plate/sealing material layer having cell encapsulated therein/backsheet, and includes the resin film according to the present invention, used as a sealing material to form he aforementioned sealing material layer.

The above-described resin film according to the present invention includes the copolymer (A), the ultraviolet absorber (B) and the silane coupling agent (C), and thus is excellent in adhesion to a glass plate, and exhibits excellent transparency and ultraviolet ray shielding properties. Further, since the ultraviolet, absorber (B) and the silane coupling agent (C) are combined with each other, the resin film does not yellow in an early stage of manufacturing, and subsequent yellowing may also be limited.

The factor by which yellowing is limited in the resin film according to the present invention is considered as described below.

For example, when the ultraviolet absorber (B) is used in combination with a silane coupling agent having an amino group in the resin film, yellowing is considered to be due to the fact that the aforementioned ultraviolet absorber (B) reacts with the aforementioned silane coupling agent. In contrast, in the present invention, it is considered that the ultraviolet absorber (B) does not easily react with the silane coupling agent (C), and thus yellowing is limited.

### EXAMPLES

The present invention is described in detail hereinafter by way of examples. However, the present invention is not limited to the following description.

### [Evaluation of Coloring Suppression]

A resin film was sandwiched by a pair of glass plates having a thickness of 1 mm to prepare a laminate. The laminate was compressed by pressing for 30 minutes after degassing at 135° C. for 3 minutes using a laminator for manufacturing a solar cell module.

The yellowness YI of a sample was measured on the basis of a standard white plate in accordance with ASTM D 1925 using a colorimeter (manufactured by Konica Minolta, Inc., product name: CM3600A). The effect of suppressing coloring of a resin film was evaluated on the basis of the following criteria.

A: YI is 10 or less

B: YI is more than 10 but not more than 20

C: YI is more than 20

### [Adhesion to a Glass Plate]

A resin film having a thickness of 1 mm and a PET sheet was laid-up on white glass having a thickness of 3 mm to prepare a laminate. The laminate was compressed by pressing for 30 minutes after degassing at 135° C. for 3 minutes using a laminator for manufacturing a solar cell module. The prepared sample was immersed in hot water for 2 hours according to a heat resistance test of laminated glass of Japanese Industrial Standards (JIS) R 3205. A 180° peel test was conducted, and the peel strength of the sample was measured. The adhesion to a glass plate of the resin film was evaluated on the basis of the following criteria.

A: peel strength is 50 N/1 inch or more

B: peel strength is 20 N/1 inch or more but less than 50 N/inch

C: peel strength is less than 20 N/1 inch

### [Transparency]

A resin film was sandwiched by a pair of glass plates having a thickness of 1 mm to prepare a laminate. The laminate was compressed by pressing for 30 minutes after degassing at 135° C. for 3 minutes using a laminator for manufacturing a solar cell module.

The haze value of the sample was measured in accordance with Japanese Industrial Standards (JIS) K 7136 using a haze meter (product name: NDH2000, manufactured by NIPPON DENSHOKU INDUSTRIES CO., LTD,). The transparency of the resin film was evaluated on the basis of the following criteria.

A: haze value is 5 or less

B: haze value is more than 5, but not more than 10

C: haze value is more than 10

### [Used Raw Material]

The raw materials used in the present examples are shown below.

### (Copolymer (A))

A-1: ethylene-acrylic acid ester-glycidyl methacrylate copolymer (constituent unit (α1): 68 mass %, constituent unit (α2): 24 mass %, glycidyl methacrylate constituent unit (α3): 8 mass %, product name: LOTADER GMA AX8900, manufactured by ARKEMA).

### (Ultraviolet Absorber (B))

B-1: 2,2′-hydroxy-4,4′-dimethoxy benzophenone (product name: UVINIL 3049, manufactured by BASF).

### (Silane Coupling Agent (C))

C-1: 3-glycidoxypropyltrimethoxysilane (product name: KBM-403, manufactured by Shin-Etsu Chemical Co., Ltd.)

### (Polymer (D))

D-1: ethylene-vinyl acetate copolymer (constituent unit of vinyl acetate: 28 mass %, product name: SEETEC VE700 manufactured by Hunan Petrochemical Industries, Ltd.)

### (Other Silane Coupling Agent (Comparison and Contrast))

F-1: N-2-(aminoethyl)-3-aminopropyltrimethoxysilane (product name:

F-2: vinyl trimethoxysilane (product name: KBM-1003, manufactured by Shin-Etsu Chemical Co., Ltd.).

### Example 1

100 parts by mass of a copolymer (A-1), 0.5 parts by mass of an ultraviolet absorber (B-1) and 0.3 parts by mass of a silane coupling agent (C-1) were kneaded using a ribbon blender, and were extrusion-molded using a single-screw extruder equipped with a T-die to prepare a resin film having a thickness of 0.5 mm.

### Example 2

A resin film was prepared in the same manner as in Example 1 except that an amount of the ultraviolet absorber (B-1) was changed to 0.3 parts by mass.

### Example 3

A resin film was prepared in the same manner as in Example 1 except that the amount of the silane coupling agent (C-1) was changed to 0.1 parts by mass.

### Example 4

A resin film was prepared in the same manner as in Example 1 except that an amount of the ultraviolet absorber (B-1) was changed to 0.7 parts by mass and the amount of the silane coupling agent (C-1) was changed to 0.5 parts by mass.

### Example 5

A resin film was prepared in the same manner as in Example 1 except that 90 parts by mass of the copolymer (A-1) and 10 parts by mass of the polymer (D-1) were mixed.

### Example 6

A resin film was prepared in the same manner as in Example 1 except that 70 parts by mass of the copolymer (A-1) and 30 parts by mass of the polymer (D-1) were mixed.

### Example 7

A resin film was prepared in the same manner as in Example 1 except that 50 parts by mass of the copolymer (A-1) and 50 parts by mass of the polymer (D-1) were mixed.

### Comparative Example 1

A resin film was prepared in the same manner as in Example 1 except that the silane coupling agent was changed to 0.3 parts by mass of a silane coupling agent (F-1).

### Comparative Example 2

A resin film was prepared in the same manner as in Example 1 except that the silane coupling agent was changed to 0.1 parts by mass of a silane coupling agent (F-1).

### Comparative Example 3

A resin film was prepared in the same manner as in Example 1 except that the silane coupling agent was changed to 0.3 parts by mass of a silane coupling agent (F-2).

### Comparative Example 4

A resin film was prepared in the same manner as in Example 1 except that the silane coupling agent was changed to 0.1 parts by mass of a silane coupling agent (F-2).

The evaluation results of Examples and Comparative Examples are shown in

Table 1.

TABLE 1

| | | | Example | | | | | | | Comparative Example | | | |
|---|---|---|---|---|---|---|---|---|---|---|---|---|---|
| | | | 1 | 2 | 3 | 4 | 5 | 6 | 7 | 1 | 2 | 3 | 4 |
| Composition | Copolymer (A) | A-1 | 100 | 100 | 100 | 100 | 90 | 70 | 50 | 100 | 100 | 100 | 100 |
| [parts by | Ultraviolet | B-1 | 0.5 | 0.3 | 0.5 | 0.7 | 0.5 | 0.5 | 0.5 | 0.5 | 0.5 | 0.5 | 0.5 |
| mass] | absorber (B) | | | | | | | | | | | | |
| | Silane coupling | C-1 | 0.3 | 0.3 | 0.1 | 0.5 | 0.3 | 0.3 | 0.3 | — | — | — | — |
| | agent (C) | | | | | | | | | | | | |
| | Other silane | F-1 | — | — | — | — | — | — | — | 0.3 | 0.1 | — | — |
| | coupling agent | F-2 | — | — | — | — | — | — | — | — | — | 0.3 | 0.1 |
| | (F) | | | | | | | | | | | | |
| | Copolymer (D) | D-1 | — | — | — | — | 10 | 30 | 50 | — | — | — | — |
| Evaluation | Coloring | YI | 8.39 | 6.34 | 8.42 | 9.74 | 8.51 | 9.17 | 9.77 | 25.82 | 23.6 | 9.28 | 9.11 |
| | suppression | Evaluation | A | A | A | A | A | A | A | C | C | A | A |
| | Adhesion to glass | | | | | | | | | | | | |
| | plate | | | | | | | | | | | | |
| | Adhesion to glass | Peel strength | >50 | >50 | >50 | >50 | >50 | >50 | >50 | >50 | >50 | 8 | 5 |
| | plate | [N/1 inch] | | | | | | | | | | | |
| | | Evaluation | A | A | A | A | A | A | A | A | A | C | C |
| | Transparency | Haze value | 2.35 | 1.94 | 2.44 | 3.71 | 3.99 | 4.13 | 4.81 | 18.9 | 14.3 | 2.39 | 3.68 |
| | | Evaluation | A | A | A | A | A | A | A | C | C | A | A |

As shown in Table 1, in Examples 1 to 4 in which the resin film includes the copolymer (A-1), the ultraviolet absorber (B-1) and the silane coupling agent (C-1) and Examples 5 to 7 in which the polymer (D-1) is further included therein, the resin film is excellent in adhesion to a glass plate and transparency, and coloring was also not observed.

On the other hand, in Comparative Examples 1 and 2 in which the ultraviolet absorber (B-1) was used in combination with the silane coupling agent having an amino group (F-1), although sufficient adhesion to a glass plate was obtained, coloring was observed, and the transparency was poor.

In Comparative Examples 3 and 4 in which the ultraviolet absorber (B-1) was used in combination with the silane coupling agent (F-2) having a vinyl group, no coloring was observed and transparency was excellent, but adhesion to a glass plate was poor.

### INDUSTRIAL APPLICABILITY

According to the present invention, the resin film is usable as a laminated glass interlayer or a sealing material for a solar cell module or the like, has excellent adhesion to a glass plate and excellent ultraviolet ray shielding properties, and does not yellow in an early stage of manufacturing as well as being capable of limiting yellowing.

What is claimed is:

1. A resin film, comprising:
(A) a copolymer which has a constituent unit derived from ethylene, a constituent unit derived from a (meth)acrylic acid ester and a constituent unit derived from a monomer having a glycidyl group;
(B) a benzophenone-based ultraviolet absorber; and
(C) a silane coupling agent having an epoxy group.

2. The resin film according to claim 1, which is a laminated glass interlayer.

3. The resin film according to claim 1, which is a sealing material for a solar cell module.
